(19) United States
(12) Patent Application Publication
(10) Pub. No.: US 2015/0292099 A1
(43) Pub. Date: Oct. 15, 2015

(54) INTERPOSER AND METHOD FOR PRODUCING THE SAME

(71) Applicant: TONG HSING ELECTRONIC INDUSTRIES, LTD., Taipei City (TW)

(72) Inventors: Shao-Pin RU, Taipei City (TW); Chien-Cheng WEI, Taipei City (TW); Sheng-Lung LIU, Taipei City (TW)

(21) Appl. No.: 14/680,158

(22) Filed: Apr. 7, 2015

(30) Foreign Application Priority Data
Apr. 9, 2014 (TW) 103113030

(51) Int. Cl. C25D 7/00; H01L 21/48; H05K 3/46; H01L 23/498

(52) U.S. Cl. CPC C25D 7/00; H01L 23/49827; H01L 23/49822; H01L 23/49811; H01L 23/49894; H01L 21/4857; H01L 21/486; H05K 3/46

(57) ABSTRACT

An interposer includes a substrate, an electrically-conductive structure, at least one dielectric layer, a redistribution structure and electrode pads. The substrate is made of a ceramic material and has first and second surfaces and via holes. The electrically-conductive structure includes conductive pads, substrate vias disposed in the via holes, and layered electrically-conductive parts. The dielectric layer is disposed on the second surface to cover the layered electrically-conductive parts. The redistribution structure penetrates the dielectric layer and is connected to the layered electrically-conductive parts. The electrode pads are disposed on a surface of the dielectric layer.

### CROSS-REFERENCE TO RELATED APPLICATION

This application claims priority of Taiwanese Patent Application No. 103113030, filed on Apr. 9, 2014.

### FIELD

The disclosure relates to an interposer, more particularly to a ceramic interposer.

### BACKGROUND

A common method for packaging semiconductors is the flip-chip technique, which utilizes metal bumps to interconnect a flip-chip die and a circuit board instead of the conventional wire bonding process. Recently, with the increasing number of internal components in semiconductor chips, and with the decreasing minimum line-width therefor, dimensions of the bump-to-bump intervals have been reduced accordingly. However, in the aspect of the circuit boards, due to process limitations, the circuit boards may usually have a minimum line-width and a minimum line-interval that are relatively larger than the bump-to-bump interval of flip-chip die, resulting in mismatch between the flip-chip die and the circuit board.

In order to solve the aforesaid mismatch problem, interposers, which include vias and redistribution layers and have various line-width scales on opposite surfaces thereof, may be utilized to connect the metal bumps of the flip-chip die and conductive circuits of the circuit board correspondingly at the opposite surfaces using soldering bumps, so as to electrically interconnect the flip-chip die and the circuit board through the vias of the interposers.

Conventional interposers are usually made of a silicon material. For instance, Taiwanese Patent Application Publication No. 201225762 discloses an electronic packaging structure which includes a conventional silicon interposer. A method for making such silicon interposer includes: dry-etching a top surface of a silicon substrate so as to form a plurality of blind holes in the silicon substrate; forming insulative layers on hole walls of the blind holes and on pattern-forming areas of the substrate to avoid generation of leak current; forming substrate vias in the blind holes by electroplating, and then forming a conductive structure which is consisted of a dielectric layer and a redistribution layer on the top surface of the silicon substrate so as to form conductive pattern lines on the pattern-forming areas of the substrate; grinding (thinning) the silicon substrate from a bottom surface to expose the substrate vias therefrom; and optionally forming conductive pattern lines on the bottom surface to be electrically connected to the substrate vias.

However, the aforesaid interposer may have some defects, ventured as follows. Since the substrate of the conventional interposer is made of silicon, the inclusion of the insulative layers are thus mandatory for preventing generation of the leak current, thereby complicating the structure of the conventional interposer and increasing production costs. Furthermore, the difference between the thermal expansion coefficients of silicon (3 ppm/° C.) and of common circuit board (20 ppm/° C.) is relatively large and may result in thermal stress, causing deformation of the conventional interposer and/or the circuit board when operating under an environment exhibiting significant temperature fluctuations. In addition, some defects may also be present in manufacturing the conventional interposer, residing in the forming of the blind holes and in the grinding of the substrate. The blind holes of the conventional interposer were manufactured by dry-etching technique which has relatively poor efficiency and may cause the blind holes to uneven depths, a trait that is hardly detectable during inspection. Furthermore, since the insulative layers and the redistribution layer are formed prior to the grinding (thinning) of the substrate, thickness deviation thereof may adversely affect thickness precision in the grinding (thinning) process.

### SUMMARY

Therefore, an object of the disclosure is to provide an interposer and/or a method for making the same which may alleviate at least one of the drawbacks of the prior art.

According to one aspect of the disclosure, an interposer for interconnecting a flip-chip die, which includes a plurality of die electrodes, and a circuit board, which includes a plurality of conductive pattern lines, includes a substrate, an electrically-conductive structure, at least one dielectric layer, a redistribution structure and a plurality of electrode pads. The substrate is made of a ceramic material and has opposite first and second surfaces and a plurality of via holes penetrating the first and second surfaces. The electrically-conductive structure includes a plurality of conductive pads disposed on the first surface of the substrate for being electrically connected to the die electrodes, a plurality of substrate vias that are respectively disposed in the via holes and that are electrically connected to the conductive pads, and a plurality of layered electrically-conductive parts that are disposed on the second surface of the substrate and that are electrically connected to the substrate vias. The at least one dielectric layer is disposed on the second surface of the substrate to cover the layered electrically-conductive parts. The redistribution structure is disposed in the at least one dielectric layer and is electrically connected to each of the layered electrically-conductive parts. The redistribution structure penetrates the at least one dielectric layer to be exposed from a surface of the at least one dielectric layer opposite to the substrate. The electrode pads are disposed on the surface of the at least one dielectric layer opposite to the substrate and are electrically connected to the redistribution structure. The electrode pads are configured to be electrically connected to the conductive pattern lines of the circuit board.

According to another aspect of the disclosure, a method for producing the aforesaid interposer includes: preparing a substrate that is made of a ceramic material, followed by forming a plurality of substrate vias, each of which penetrates the substrate and has two opposite ends respectively protruding from opposite first and second surfaces of the substrate; grinding the substrate from the first and second surfaces thereof, so that the two opposite ends of each of the substrate vias are flush respectively with the first and second surfaces of the substrate; forming on the first surface of the substrate a plurality of conductive pads that are electrically connected to the substrate vias; forming on the second surface of the substrate a plurality of layered electrically-conductive parts that are electrically connected to the substrate vias; disposing at least one dielectric layer to cover the layered electrically-conductive parts; forming a redistribution structure in the at least one dielectric layer to be in electrical connection with the layered electrically-conductive parts, the redistribution structure penetrating the at least one dielectric layer to be exposed from a surface of the at least one dielectric layer opposite to the substrate; and forming a plurality of electrode pads on the surface of the at least one dielectric layer to be electrically connected to the redistribution structure.

### BRIEF DESCRIPTION OF THE DRAWINGS

Other features and advantages of the disclosure will become apparent in the following detailed description of the exemplary embodiments with reference to the accompanying drawings, of which:

FIG. 1 is a schematic sectional view illustrating an electronic package module that includes an exemplary embodiment of an interposer according to the disclosure;

FIG. 2 is a flow chart illustrating a method for producing the exemplary embodiment of the interposer; and

FIGS. 3 to 9 are schematic diagrams illustrating steps of the method.

### DETAILED DESCRIPTION

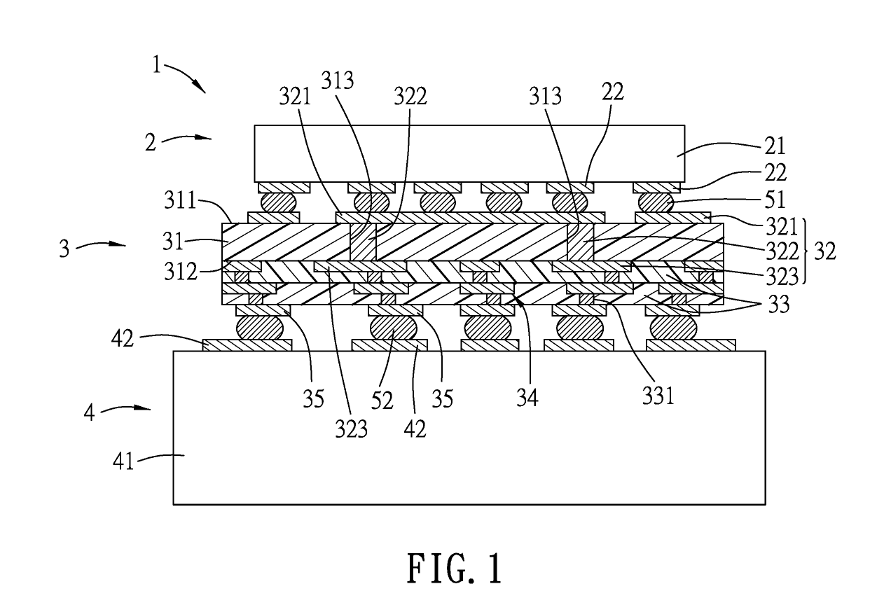

Referring to FIG. 1, an electronic package module 1 is shown to include a flip-chip die 2, a circuit board 4 and an interposer 3 of the exemplary embodiment according to the present disclosure. The flip-chip die 2 includes a die body 21, and a plurality of die electrodes 22 disposed on a bottom surface of the die body 21. The circuit board 4 includes a main body 41, and a plurality of conductive pattern lines 42 disposed on a top surface of the main body 41. The flip-chip die 2 and the circuit board 4 are connective to the interposer 3 respectively by first and second soldering structures 51, 52. The interposer 3 of the present disclosure includes a substrate 31, an electrically-conductive structure 32, at least one dielectric layer 33, a redistribution structure 34 and a plurality of electrode pads 35.

The substrate 31 is substantially made of a ceramic material and has opposite first and second surfaces 311, 312. As shown in FIG. 1, the substrate 31 is formed with a plurality of via holes 313 penetrating the first and second surfaces 311, 312. In this embodiment, the ceramic material for the substrate 31 may be selected from the group consisting of aluminum oxide, aluminum nitride, silicon nitride, zirconia, zirconia-toughened aluminum oxide, beryllium oxide and combinations thereof.

The electrically-conductive structure 32 includes a plurality of conductive pads 321, a plurality of substrate vias 322 and a plurality of layered electrically-conductive parts 323. The conductive pads 321 are disposed on the first surface 311 of the substrate 31 for being electrically connected to the die electrodes 22 of the flip-chip die 2. The substrate vias 322 are respectively disposed in the via holes 313 and are electrically connected to the conductive pads 321. The layered electrically-conductive parts 323 are disposed on the second surface 312 of the substrate 31 and are electrically connected to the substrate vias 322. The conductive pads 321, the substrate vias 322 and the layered electrically-conductive parts 323 constitute cooperatively a plurality of conductive paths through the substrate 31.

The at least one dielectric layer 33 is disposed on the second surface 312 of the substrate to cover the layered electrically-conductive parts 323. The at least one dielectric layer 33 may be made of a polymeric material, such as polyimide in this embodiment.

The redistribution structure 34 is disposed in the at least one dielectric layer 33 and is electrically connected to the layered electrically-conductive parts 323. In addition, the redistribution structure 34 penetrates the at least one dielectric layer 33 to be exposed from a surface of the at least one dielectric layer 33 opposite to the substrate 31.

As shown in FIG. 1, in this embodiment, the at least one dielectric layer 33 includes two dielectric layers stacked on the second surface 312 of the substrate 31, but the number of the dielectric layer is not limited thereto according to the present disclosure.

The electrode pads 35 are disposed on the surface of the at least one dielectric layer 33 and are electrically connected to the redistribution structure 34. The electrode pads 35 are configured to be electrically connected to the conductive pattern lines 42 of the circuit board 4. As such, the electrically-conductive structure 32, the redistribution structure 34 and the electrode pads 35 constitute a plurality of conductive paths interconnecting the die electrodes 22 of the flip-chip die 2 and the conductive pattern lines 42 of the circuit board 4.

It should be noted that, the conductive pads 321, the substrate vias 322, the layered electrically-conductive parts 323, the redistribution structure 34 and the electrode pads 35 may be made of a metal material, e.g., titanium, nickel, silver, copper, or combinations thereof.

The interposer of the present disclosure may have the following advantages:

(1) the ceramic substrate 31 provides electrical insulation to avoid leak current problems that might occur in a semiconductor device including the conventional silicon interposer, thereby removing the need for additional insulative layers;

(2) the ceramic substrate 31 exhibits relatively superior heat conductivity and high heat-dissipation efficiency and is thus suitable for high power flip-chip dies or other semiconductor components;

(3) the ceramic substrate 31 exhibits good mechanical strength and thus provides high reliability; and

(4) the thermal expansion coefficient of the ceramic substrate 31 substantially ranges from 6 to 10 ppm/° C., and is in between that of the flip-chip die 2 and that of the circuit board 4, so that the thermal stress of the electronic package module 1 may be effectively reduced.

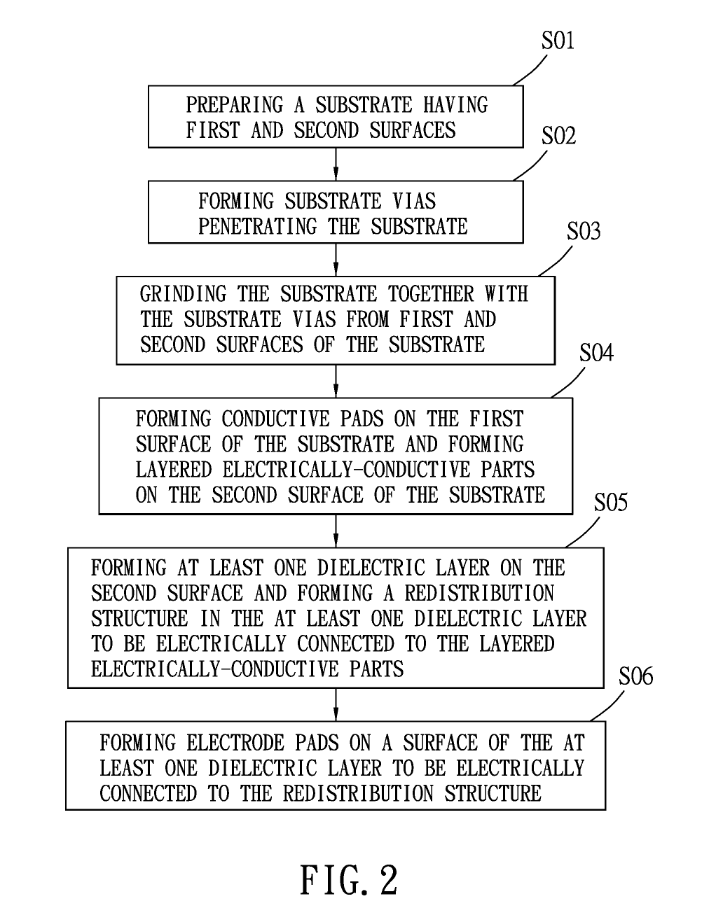

Referring to FIGS. 2 to 9, a method for producing the aforesaid interposer of the exemplary embodiment according to the present disclosure includes steps as follows.

Step S01: preparing a substrate 31 that is made of a ceramic material and that has opposite first and second surfaces 311, 312.

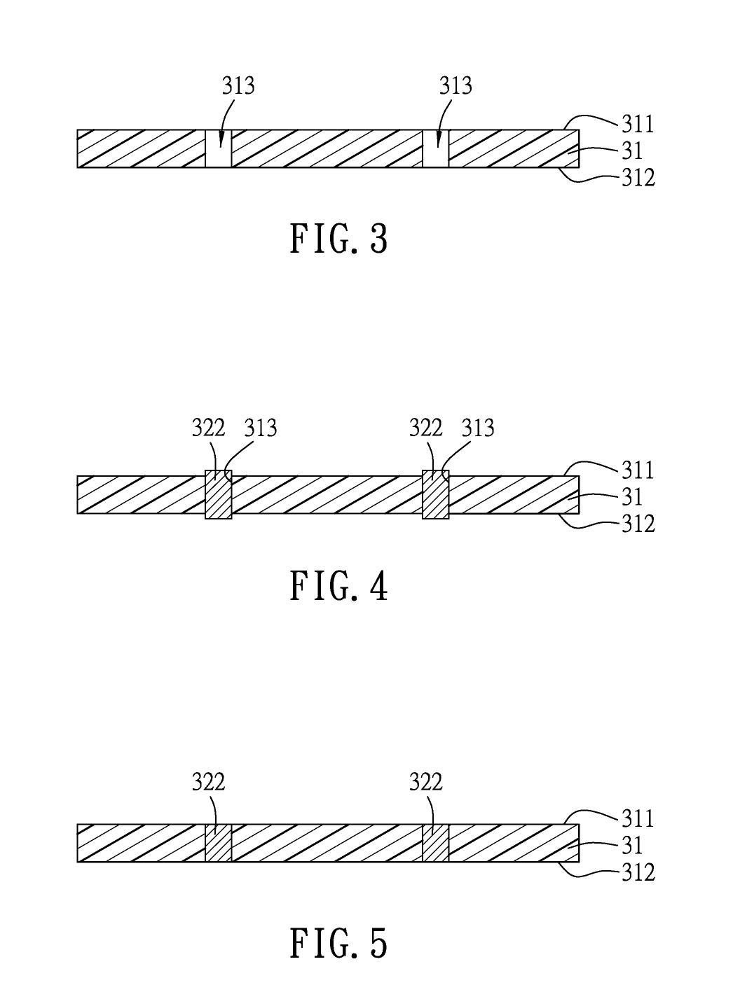

Step S02: forming a plurality of substrate vias 322 respectively in the via holes 313 and penetrating the substrate 3 (see FIGS. 3 and 4). The forming of the substrate vias 322 may include forming a plurality of via holes 313 penetrating the first and second surfaces 311, 312 (see FIG. 3), followed by forming the substrate vias 322 in the via holes 313 (see FIG. 4). As shown in FIG. 4, each substrate vias 322 has two opposite ends that respectively protrude from the first and second surfaces 311, 312 of the substrate 31. In this embodiment, the forming of the via holes 313 may be conducted with laser or mechanical drilling, but is not limited thereto according to the present disclosure. In this embodiment, the forming of the substrate vias 322 in the via holes 313 may be conducted by electroplating.

Step S03: grinding the substrate 31 together with the substrate vias 322 from the first and second surfaces 311, 312, such that the two opposite ends of each of the substrate vias 322 are flush respectively with the first and second surfaces 311, 312 of the substrate 31 (see FIG. 5). The grinding of the substrate 31 and the substrate vias 322 may be conducted by mechanical polishing or by chemical mechanical polishing methods.

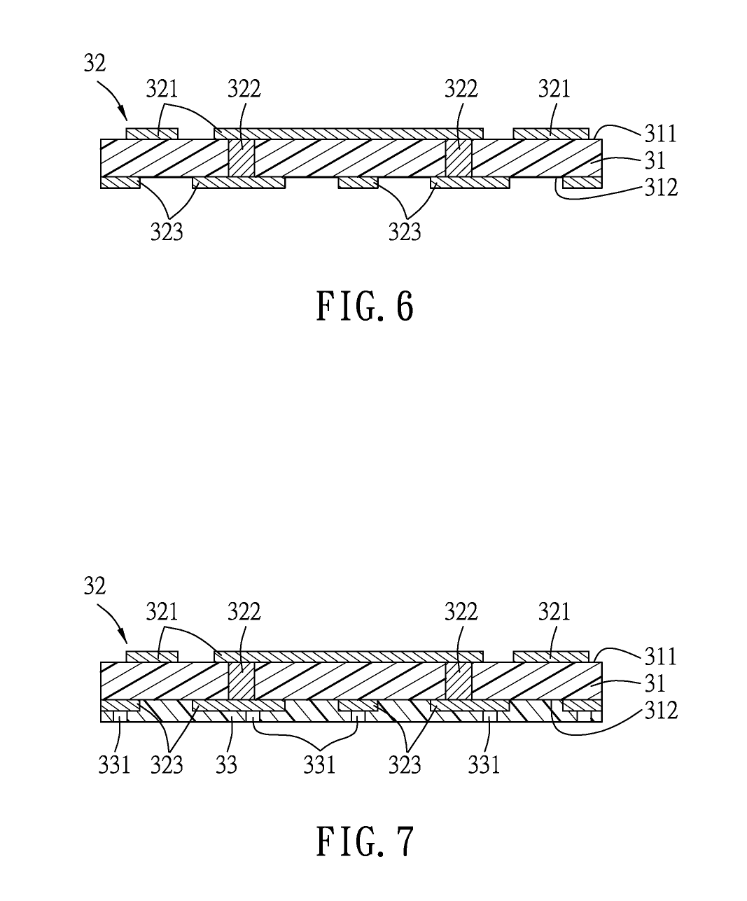

Step S04: forming on the first surface 311 of the substrate 31 a plurality of conductive pads 321 that are electrically connected to the substrate vias 322, and forming on the second surface of the substrate a plurality of layered electrically-conductive parts 323 that are electrically connected to the substrate vias 322 (see FIG. 6). The conductive pads 321, the substrate vias 322 and the layered electrically-conductive parts 323 constitute an electrically-conductive structure 32. In this embodiment, the forming of the conductive pads 321 and the layered electrically-conductive parts 323 may be conducted by a lift-off process, including photolithography, film deposition and photoresist removal. However, in other embodiments, the forming of the conductive pads 321 and the layered electrically-conductive parts 323 may be conducted by an electroplating procedure incorporating with a patterning process, such as etching, in accordance with the present disclosure.

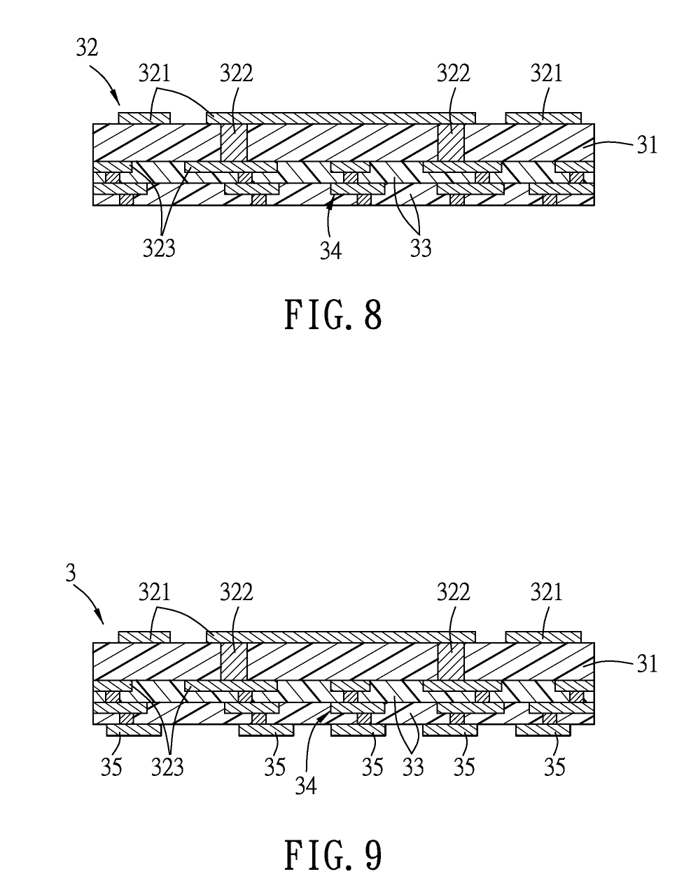

Step S05: disposing at least one dielectric layer 33 to cover the layered electrically-conductive parts 323, and forming a redistribution structure 34 in the at least one dielectric layer 33 to be in electrical connection with each of the layered electrically-conductive parts 323 (see FIGS. 7 and 8). The redistribution structure 34 penetrates the at least one dielectric layer 33 so as to be exposed from a surface of the at least one dielectric layer 33 opposite to the substrate 31. Since the at least one dielectric layer 33 of this embodiment includes two or more dielectric layers 33, the forming of the redistribution structure 34 may include forming a plurality of blind holes 331 in one dielectric layer 33 first, where the blind holes 331 are in registration with a respective one of the layered electrically-conductive parts 323, and forming at least part of the redistribution structure 34 in the blind holes 331. The aforesaid steps may then be repeatedly conducted in accordance with the number of the dielectric layers 33. In this embodiment, the forming of the redistribution structure 34 may be conducted by electroplating or by film deposition, but is not limited thereto in accordance with the present disclosure.

Step S06: forming a plurality of electrode pads 35 on the surface of the at least one dielectric layer 33 so as to be electrically connected to the redistribution structure 34 (see FIG. 9). Similar to the forming of the conductive pads 321, the forming of the electrode pads 35 may be conducted by the lift-off process or by the electroplating procedure incorporating with the patterning process.

Since the forming of the via holes 313 is conducted with laser or by mechanical drilling according to the present disclosure, the aforesaid drawback of the prior art can be prevented. In addition, the grinding of the substrate 31 is conducted prior to the forming of the conductive pads 321, the forming of the at least one dielectric layer 33, the forming of the redistribution structure 34 and the forming of the electrode pads 35, so that precision for the grinding of the substrate 31 may not be adversely affected.

While the disclosure has been described in connection with what is considered the exemplary embodiment, it is understood that this disclosure is not limited to the disclosed embodiment but is intended to cover various arrangements included within the spirit and scope of the broadest interpretation so as to encompass all such modifications and equivalent arrangements.

What is claimed is:

1. An interposer for electrically interconnecting a flip-chip die, which includes a plurality of die electrodes, and a circuit board, which includes a plurality of conductive pattern lines, said interposer comprising:
a substrate that is made of a ceramic material and that has opposite first and second surfaces and a plurality of via holes penetrating said first and second surfaces;
an electrically-conductive structure including
a plurality of conductive pads disposed on said first surface of said substrate for being electrically connected to the die electrodes,
a plurality of substrate vias that are respectively disposed in said via holes and that are electrically connected to said conductive pads, and
a plurality of layered electrically-conductive parts that are disposed on said second surface of said substrate and that are electrically connected to said substrate vias;
at least one dielectric layer disposed on said second surface of said substrate to cover said layered electrically-conductive parts;
a redistribution structure disposed in said at least one dielectric layer and electrically connected to each of said layered electrically-conductive parts, said redistribution structure penetrating said at least one dielectric layer to be exposed from a surface of said at least one dielectric layer opposite to said substrate; and
a plurality of electrode pads that are disposed on said surface of said at least one dielectric layer and that are electrically connected to said redistribution structure, said electrode pads being configured to be electrically connected to the conductive patterns lines of the circuit board.

2. The interposer according to claim 1, wherein:
the ceramic material is selected from the group consisting of aluminum oxide, aluminum nitride, silicon nitride, zirconia, zirconia-toughened aluminum oxide, beryllium oxide and combinations thereof; and
said at least one dielectric layer is made of a polymeric material.

3. The interposer according to claim 2, wherein the polymeric material is polyimide.

4. The interposer according to claim 1, wherein said at least one dielectric layer includes a plurality of dielectric layers stacked on said second surface of said substrate, said redistribution structures penetrating said dielectric layers.

5. The interposer according to claim 1, wherein said conductive pads, said layered electrically-conductive parts, said substrate vias, said redistribution structures and said electrode pads are made of a metal material that is selected from the group consisting of titanium, nickel, silver, copper and combinations thereof.

6. A method for producing an interposer, comprising:
preparing a substrate that is made of a ceramic material, followed by forming a plurality of substrate vias each of which penetrates the substrate and has two opposite ends respectively protruding from opposite first and second surfaces of the substrate;
grinding the substrate together with the substrate vias from the first and second surfaces, such that the two opposite ends of each of the substrate vias are flush respectively with the first and second surfaces of the substrate;
forming on the first surface of the substrate a plurality of conductive pads that are electrically interconnected to the substrate vias;
forming on the second surface of the substrate a plurality of layered electrically-conductive parts that are electrically connected to the substrate vias;
disposing at least one dielectric layer to cover the layered electrically-conductive parts;
forming a redistribution structure in the at least one dielectric layer to be in electrical connection with each of the layered electrically-conductive parts, the redistribution structure penetrating the at least one dielectric layer so as to be exposed from a surface of the at least one dielectric layer opposite to the substrate; and
forming a plurality of electrode pads on the surface of the at least one dielectric layer to be electrically connected to the redistribution structure.

7. The method of claim 6, wherein the forming of the substrate vias includes forming a plurality of via holes with laser drilling, and forming the substrate vias in the via holes by electroplating.

8. The method of claim 6, wherein the forming of the redistribution structure includes:
forming a plurality of blind holes in the at least one dielectric layer, each of the blind holes being in registration with a respective one of the layered electrically-conductive parts; and
forming the redistribution structure in the blind holes by electroplating.

9. The method of claim 6, wherein the forming of the conductive pads and the forming of the electrode pads are conducted by photolithography and metal deposition technologies.
